(19) United States
(12) Patent Application Publication
(10) Pub. No.: US 2020/0222989 A1
(43) Pub. Date: Jul. 16, 2020

(54) COATED TOOL AND CUTTING TOOL INCLUDING SAME

(71) Applicant: KYOCERA CORPORATION, Kyoto-shi, Kyoto (JP)

(72) Inventors: Dan He, Saitama-shi, Saitama (JP); Tsuyoshi Yamasaki, Satsumasendai-shi, Kagoshima (JP)

(21) Appl. No.: 16/642,410

(22) PCT Filed: Aug. 24, 2018
(86) PCT No.: PCT/JP2018/031394

§ 371 Date: Feb. 27, 2020

(30) Foreign Application Priority Data
Aug. 29, 2017 (JP) 2017-164107

(51) Int. Cl. B23B 27/14; B32B 15/01; C23C 14/16

(52) U.S. Cl. CPC B23B 27/148; B23B 2228/105; C23C 14/16; B32B 15/016

(57) ABSTRACT

A coated tool may include a base member and a coating layer located on the base member. The coating layer may include a plurality of AlTi layers including aluminum and titanium, and a plurality of AlCr layers including aluminum and chromium. The AlTi layers and the AlCr layers may be located alternately one upon another. The coating layer may include a plurality of first regions where a thickness of each of the AlTi layers becomes larger as going away from the base member, and a plurality of second regions where a thickness of each of the AlTi layers becomes smaller as going away from the base member. The first regions and the second regions may be located alternately one upon another in a thickness direction of the coating layer.

### CROSS-REFERENCE TO RELATED APPLICATIONS

This application is a national stage entry according to 35 U.S.C. 371 of PCT Application No. PCT/JP2018/031394 filed on Aug. 24, 2018, which claims priority to Japanese Application No. 2017-164107 filed on Aug. 29, 2017, which are entirely incorporated herein by reference.

### TECHNICAL FIELD

The present disclosure relates to a coated tool for use in a cutting process, and a cutting tool including the coated tool.

### BACKGROUND

As a coated tool for use in a cutting process, such as a turning process and a milling process, a surface coated cutting tool (coated tool) may be discussed, for example, in Japanese Unexamined Patent Publication No. 2017-042906 (Patent Document 1). The coated tool discussed in Patent Document 1 may include a tool base member and a hard coating layer in which an A layer represented by (Ti_{1-z}Al_{z})N and a B layer represented by (Cr_{1-x-y}AlₓM_{y})N may be alternately laminated one upon another on a surface of the tool base member. A thickness of the A layer and a thickness of the B layer may be kept constant.

As another coated tool, a multilayer coated cutting tool (coated tool) may be discussed, for example, in Japanese Unexamined Patent Publication No. 2001-521447 (Patent Document 2). A coating may include a multilayer structure applied over a main body in the coated tool discussed in Patent Document 2. Any repeating period may not be included in continuity of individual layer thicknesses in the coating, thus being nonperiodic throughout the entirety of the multilayer structure.

### SUMMARY

A coated tool according an aspect of the present disclosure may include a base member and a coating layer located on the base member. The coating layer may include a plurality of AlTi layers including aluminum and titanium, and a plurality of AlCr layers including aluminum and chromium. The AlTi layers and the AlCr layers may be located alternately one upon another. The coating layer may include a plurality of first regions where a thickness of each of the AlTi layers may become larger as going away from the base member, and a plurality of second regions where a thickness of each of the AlTi layers may become smaller as going away from the base member. The first regions and the second regions may be located alternately one upon another in a thickness direction of the coating layer.

A cutting tool according to an aspect of the present disclosure may include a holder including a pocket located at a side of a front end of the holder, and a coated tool according to an aspect of the present disclosure, which is located in the pocket.

### BRIEF DESCRIPTION OF THE DRAWINGS

FIG. 1 is a perspective view illustrating a coated tool in a non-limiting first embodiment of the present disclosure;

FIG. 2 is a sectional view taken along line A-A in the coated tool illustrated in FIG. 1;

FIG. 3 is an enlarged view of a region B1 illustrated in FIG. 2;

FIG. 4 is an enlarged view of the region B1 illustrated in FIG. 2;

FIG. 5 is a diagram illustrating a coated tool in a non-limiting second embodiment of the present disclosure, which corresponds to FIGS. 3 and 4 in the non-limiting first embodiment;

FIG. 6 is a diagram illustrating the coated tool in the non-limiting second embodiment of the present disclosure, which corresponds to FIGS. 3 and 4 in the non-limiting first embodiment;

FIG. 7 is a diagram illustrating the coated tool in the non-limiting second embodiment of the present disclosure, which corresponds to FIGS. 3 and 4 in the non-limiting first embodiment;

FIG. 8 is a plan view illustrating a cutting tool in a non-limiting embodiment of the present disclosure; and

FIG. 9 is an enlarged view of a region B2 illustrated in FIG. 8.

### DETAILED DESCRIPTION

<Coated Tools>

Coated tools in various non-limiting embodiments of the present disclosure are described in detail below with reference to the drawings. For the sake of description, the drawings referred to in the following illustrate, in a simplified form, only main members necessary for describing the non-limiting embodiments. The coated tools are therefore capable of including any arbitrary structural member not illustrated in the drawings referred to. Sizes of the members in each of the drawings faithfully represent neither sizes of actual structural members nor size ratios of these members. These are also true for a non-limiting cutting tool described later.

### First Non-Limiting Embodiment

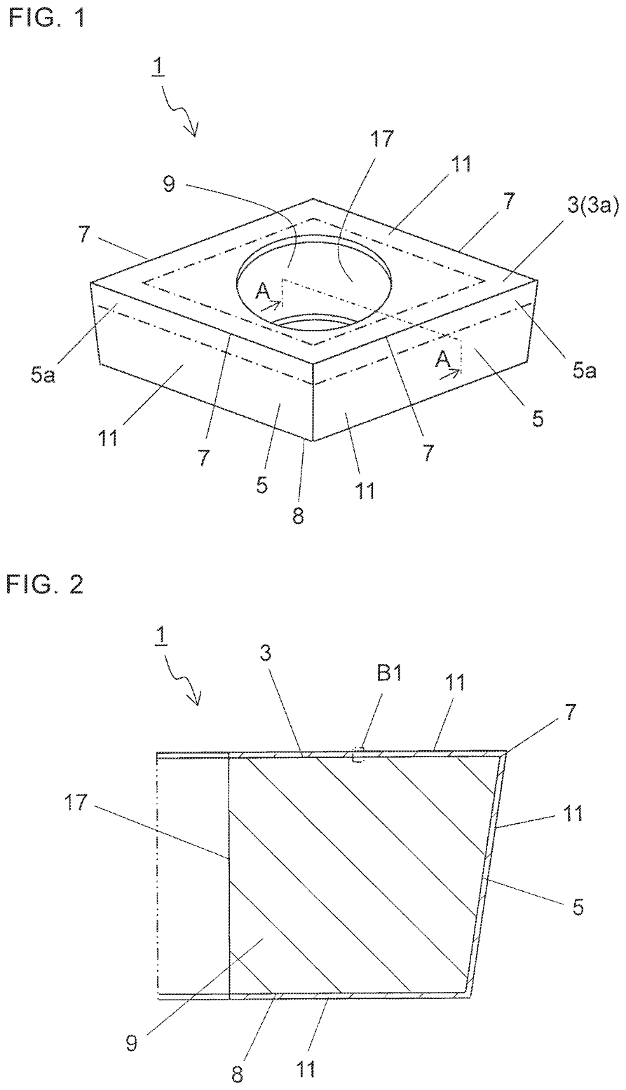

The coated tool 1 in the first non-limiting embodiment has a quadrangular plate shape and includes a first surface 3 (upper surface in FIG. 1) having a quadrangular shape, a second surface 5 (side surface in FIG. 1), and a cutting edge 7 located on at least a part of a ridge line where the first surface 3 intersects with the second surface 5. The coated tool 1 in the first non-limiting embodiment further includes a third surface 8 (lower surface in FIG. 1) having a quadrangular shape.

The entirety of an outer periphery of the first surface 3 may serve as the cutting edge 7 in the coated tool 1 of the first non-limiting embodiment. The coated tool 1 is not limited to the above configuration. For example, the cutting edge 7 may be located on only one side or a part of the first surface 3 having the quadrangular shape.

The first surface 3 may at least partially include a rake surface region 3a. A region in the first surface 3 which is located along the cutting edge 7 serves as the rake surface region 3a in the first non-limiting embodiment. The second surface 5 may include at least partially a flank surface region 5a. A region in the second surface 5 which is located along the cutting edge 7 serves as the flank surface region 5a in the first non-limiting embodiment. In other words, the cutting edge 7 is located on an intersecting part of the rake surface region 3a and the flank surface region 5a.

A boundary between the rake surface region 3a and other region on the first surface 3, and a boundary between the flank surface region 5a and other region on the second surface 5 are indicated by a chain line in FIG. 1. Because FIG. 1 illustrates a non-limiting embodiment in which all the ridge line where the first surface 3 intersects with the second surface 5 serves as the cutting edge 7, FIG. 1 illustrates a ring-shaped chain line along the cutting edge 7 on the first surface 3.

A size of the coated tool 1 is not particularly limited. For example, a length of one side of the first surface 3 is settable to approximately 3-20 mm in the first non-limiting embodiment. A height from the first surface 3 to the third surface 8 located on opposite side of the first surface 3 is settable to approximately 5-20 mm.

As illustrated in FIGS. 1 and 2, the coated tool 1 includes the base member 9 having the quadrangular plate shape, and a coating layer 11 that coats a surface of the base member 9 in the first non-limiting embodiment. The coating layer 11 may cover the whole or only a part of the surface of the base member 9. If the coating layer 11 covers only the part of the base member 9, it can be said that the coating layer 11 is located on at least the part of the base member 9.

The coating layer 11 is located on at least the rake surface region 3a along the cutting edge 7 on the first surface 3 and the flank surface region 5a along the cutting edge 7 on the second surface 5 in the first non-limiting embodiment. FIG. 1 illustrates a non-limiting embodiment in which the coating layer 11 is located on the entirety of the first surface 3 including the rake surface region 3a and on the entirety of the second surface 5 including the flank surface region 5a. A thickness of the coating layer 11 is settable to, for example, approximately 0.1-10 μm. The thickness of the coating layer 11 as a whole may be constant or may be changed depending on location.

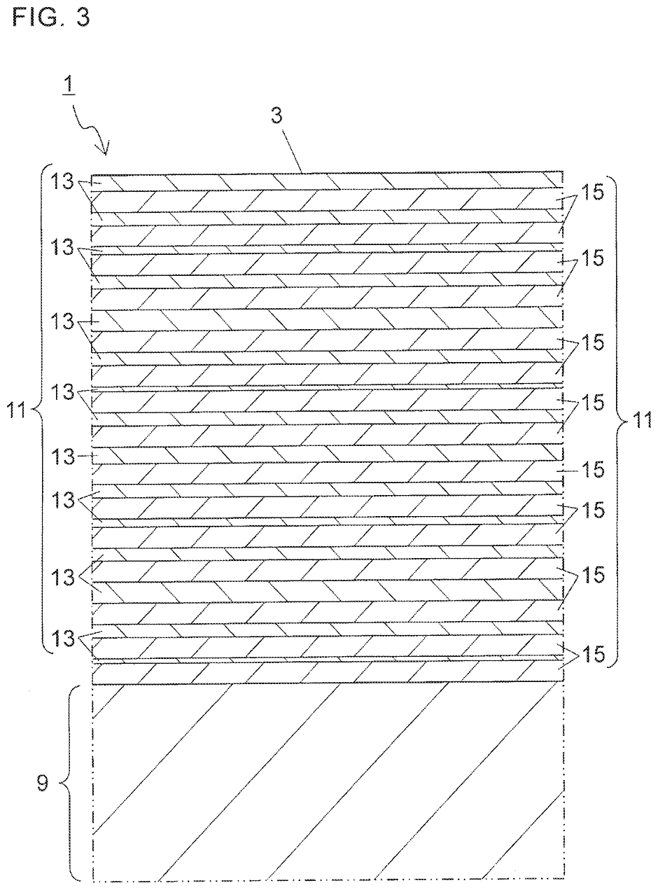

As illustrated in FIG. 3, the coating layer 11 includes a plurality of AlTi layers 13 including at least aluminum (Al) and titanium (Ti), and a plurality of AlCr layers 15 including aluminum and chromium (Cr). The plurality of AlTi layers 13 and the plurality of AlCr layers 15 are located alternately one upon another in the coating layer 11. In other words, the coating layer 11 includes a structure in which AlTi layers 13 and AlCr layers 15 are alternately laminated one upon another. A laminate structure of the coating layer 11 is evaluable by cross section measurement using a scanning electron microscopy (SEM) or transmission electron microscopy (TEM).

Although the AlTi layer 13 may be composed only of aluminum and titanium, the AlTi layer 13 may also include a metal component, such as Si, Nb, Hf, V, Ta, Mo, Zr, Cr and W, in addition to aluminum and titanium. The sum of the content ratios of aluminum and titanium is higher than that of the metal component in the AlTi layer 13. Specifically, because the sum of the content ratios of aluminum and titanium is higher than that of the metal component, it can be considered that the AlTi layer 13 includes aluminum and titanium as a main component. The term “content ratio” indicates a content ratio in terms of atomic ratio.

The plurality of AlTi layer 13 individually include aluminum and titanium as a main component, and the content ratio of titanium is settable to, for example, 40-70%. The content ratio of titanium is settable to, for example, 25-50%. The content ratio of aluminum may be higher than the content ratio of titanium in each of the AlTi layers 13. Alternatively, the content ratio of titanium may be higher than the content ratio of aluminum in each of the AlTi layers 13.

The AlTi layers 13 may be composed only of metal components including aluminum and titanium. Alternatively, the AlTi layers 13 may be composed of nitride, carbide or carbonitride of metal components including aluminum and titanium.

The AlCr layers 15 may be composed only of aluminum and chromium, or alternatively, may include a metal component, such as Nb, Hf, V, Ta, Mo, Zr, Ti and W, in addition to aluminum and chromium. A sum of content ratios of aluminum and chromium is higher than that of the metal component in the AlCr layer 15. Specifically, because the sum of the content ratios of aluminum and chromium is higher than that of the metal component, it can be considered that the AlCr layers 15 include aluminum and chromium as a main component.

Thus, the plurality of AlCr layers 15 individually include aluminum and chromium as a main component. The content ratio of aluminum is settable to, for example, 20-60%. The content ratio of chromium is settable to, for example, 40-80%. The content ratio of aluminum may be higher than the content ratio of chromium in each of the AlCr layers 15. Alternatively, the content ratio of chromium may be higher than the content ratio of aluminum in each of the AlCr layers 15.

The AlCr layers 15 may be composed only of metal components including aluminum and chromium. Alternatively, the AlCr layers 15 may be composed of nitride, carbide or carbonitride of metal components including aluminum and chromium.

Compositions of the AlTi layers 13 and the AlCr layers 15 are measurable using, for example, energy dispersive X-ray spectroscopy (EDS) or X-ray photoelectron spectroscopy (XPS).

Wear resistance of the coating layer 11 can be enhanced because the coating layer 11 includes the AlTi layers 13. Fracture resistance of the coating layer 11 can be enhanced because the coating layer 11 includes the AlCr layers 15. Strength of the coating layer 11 can be enhanced as a whole because the coating layer 11 includes the structure in which the AlTi layers 13 and the AlCr layers 15 are located alternately one upon another. The strength becomes higher with decreasing the thickness of the AlTi layers 13 and the AlCr layers 15.

The number of the AlTi Layers 13 and the number of the AlCr layers 15 are not limited to a specific value. The number of the AlTi layers 13 and the number of the AlCr layers 15 may be individually six or more, and the number thereof is settable to, for example, 6 to 500.

A thickness of each of the AlTi Layers 13 and a thickness of each of the AlCr layers 15 are not limited to a specific value, but are individually settable to 5-100 nm.

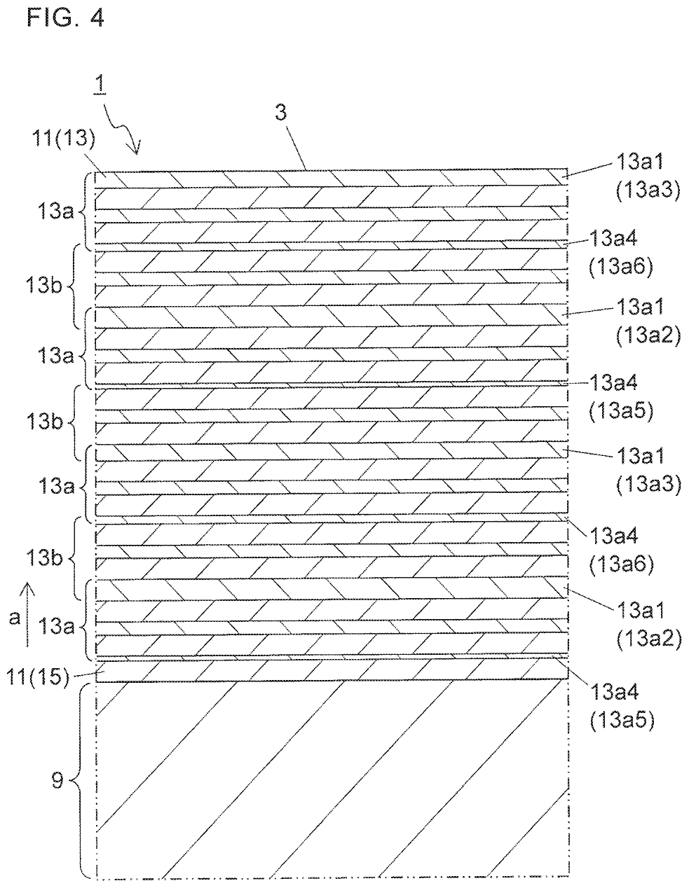

The coating layer 11 includes a plurality of first regions 13a where the thickness of each of the AlTi layers 13 becomes larger as going away from the base member 9, and a plurality of second regions 13b where the thickness of each of the AlTi layers 13 becomes smaller as going away from the base member 9 in the first non-limiting embodiment as illustrated in FIG. 4. The first regions 13a and the second regions 13b are located alternately one upon another in a thickness direction “a” of the coating layer 11. The thickness direction “a” of the coating layer 11 may be rephrased as a laminate direction of the AlTi layers 13 and the AlCr layers 15 in the coating layer 11. These configurations contribute to a coated tool 1 having excellent durability as described later.

Because the coating layer 11 includes the first regions 13a and the second regions 13b in the first non-limiting embodiment as described above, the individual AlTi layers 13 do not have a constant thickness. Some of the AlTi layers 13 have a relatively large thickness, and some of them have a relatively small thickness.

Thus, because the coating layer 11 includes the plurality of AlTi layers 13 having the relatively large thickness, these contribute to enhancing hardness and wear resistance of the coating layer 11. Because the coating layer 11 also includes the plurality of AlTi layers 13 having the relatively small thickness, these contribute to enhancing strength of the coating layer 11. The durability of the coating layer 11 can be enhanced because the wear resistance and strength of the coating layer 11 can be enhanced as described above.

Furthermore, the thickness of each of the AlTi layers 13 becomes larger as going away from the base member 9 in the first regions 13a. The thickness of each of the AlTi layers 13 becomes smaller as going away from the base member 9 in the second regions 13b. Hence, a region where the thickness of the AlTi layers 13 changes extremely is less likely to occur inside the coating layer 11.

If the thickness of the AlTi layers 13 is changed extremely, there occurs, for example, a region where deformation of the AlTi layers 13 changes significantly due to a load, such as internal stress due to deformation under load in use or differential shrinkage during manufacturing. Accordingly, a crack may occur in this region. However, because the coating layer 11 includes the plurality of first regions 13a and the plurality of second regions 13b in the first non-limiting embodiment, the region where the thickness of the AlTi layers 13 changes extremely is less likely to occur inside the coating layer 11. The coating layer 11 is therefore less susceptible to cracking, thus leading to further enhanced durability.

Additionally, the first regions 13a and the second regions 13b are located alternately one upon another in the thickness direction “a” in the first non-limiting embodiment. This ensures that the AlTi layers 13 having the relatively large thickness and the AlTi layers 13 having the relatively small thickness are located in a wide range in the thickness direction “a” in the coating layer 11. Hence, the above-mentioned load can be absorbed in the wide range in the thickness direction “a” in the coating layer 11, and the durability can also be enhanced, thereby enhancing the durability of the coating layer 11 as a whole.

For the above reasons, the coated tool 1 in the first non-limiting embodiment has much excellent durability. The coated tool 1 in the first non-limiting embodiment is therefore capable of carrying out a cutting process that is stable over a long term.

The number of the AlTi layers 13 in each of the first regions 13a and the second regions 13b may be three or more, and is settable to, for example, 3 to 20. The number of the AlTi layers 13 in the individual first regions 13a may be identical or different. Similarly, the number of the AlTi layers 13 in each of the second regions 13b may be identical or different. The number of the first regions 13a and the number of the second regions 13b may be two or more, and are settable to, for example, 2 to 100.

The AlTi layer 13 located most away from the base member 9 in each of the plurality of first regions 13a is a first AlTi layer 13a1. The number of the AlTi layers 13 located each between the first AlTi layers 13a1 may be approximately the same. In other words, the plurality of first AlTi layers 13a1 may be located periodically in the thickness direction “a” of the coating layer 11. If satisfying this configuration, the plurality of first AlTi layers 13a1 are located regularly inside the coating layer 11. Therefore, a load exerted on the coating layer 11 can be received in a well-balanced manner, leading to enhanced durability.

The number of the AlTi layers 13 located each between the plurality of first AlTi layers 13a1 is not limited to a specific value, but it is settable to, for example, 2 to 40. The phrase that “the number of the AlTi layers 13 located each between the plurality of first AlTi layers 13a1 is approximately the same” denotes a concept including not only cases where the number of the AlTi layers 13 is strictly identical, but also cases where the number of the AlTi layers 13 is substantially identical.

Specifically, if the number of the AlTi layers 13 located each between the plurality of first AlTi layers 13a1 is 11 to 21, there may be a difference of ±1 in the number of the AlTi layers 13. If the number of the AlTi layers 13 located each between the plurality of first AlTi layers 13a1 is 21-40, there may be a difference of ±2 in the number of the AlTi layers 13.

The plurality of first AlTi layers 13a1 may have the same thickness. Alternatively, in the first AlTi layers 13a1 in the first regions 13a adjacent to each other, a magnitude relation in terms of thickness value may be repeated in the thickness direction “a” of the coating layer 11. In other words, the plurality of first AlTi layers 13a1 (coating layer 11) may further include a part where layers 13a2 having a relatively large thickness and layers 13a3 having a relatively small thickness are located alternately one upon another in the thickness direction “a” of the coating layer 11.

If the plurality of first AlTi layers 13a1 include the part where the layers 13a2 and the layers 13a3 are located alternately one upon another, the plurality of AlTi layers 13 (coating layer 11) include a part where the layers 13a2 and the layers 13a3 are located alternately one upon another in the thickness direction “a”. The layers 13a2 have the relatively large thickness and therefore tend to receive the load exerted on the coating layer 11. The layers 13a3 have the relatively small thickness, and therefore adhesion is less likely to deteriorate. Consequently, the adhesion between the adjacent layers can be enhanced in a well-balanced manner while receiving the load exerted on the coating layer 11 in a well-balanced manner.

The AlTi layers 13 located closest to the base member 9 in each of the plurality of first regions 13a is a second AlTi layer 13a4. The number of the AlTi layers 13 located each between the second AlTi layers 13a4 may be approximately the same. In other words, the plurality of second AlTi layers 13a4 may be periodically located in the thickness direction “a” of the coating layer 11. If satisfying this configuration, the plurality of second AlTi layers 13a4 are located regularly inside the coating layer 11. Therefore, the adhesion between the adjacent layers can be enhanced in a well-balanced manner.

The number of the AlTi layers 13 located each between the plurality of second AlTi layers 13a4 is not limited to a specific value, but it is settable to, for example, 2 to 40. The phrase that “the number of the AlTi layers 13 located each between the plurality of second AlTi layers 13a4 is approximately the same” can be defined similarly to the phrase that “the number of the AlTi layers 13 located each between the plurality of first AlTi layers 13a1 is approximately the same.”

The plurality of second AlTi layers 13a4 may have the same thickness. Alternatively, a magnitude relation in terms of thickness value may be repeated in the thickness direction “a” of the coating layer 11 in the second AlTi layer 13a4 in the adjacent first regions 13a. In other words, the plurality of second AlTi layers 13a4 (coating layer 11) may further include a part where layers 13a5 having a relatively small thickness and layers 13a6 having a relatively large thickness are located alternately one upon another in the thickness direction “a” of the coating layer 11.

If the plurality of second AlTi layers 13a4 include the part where the layers 13a5 and the layers 13a6 are located alternately one upon another, the plurality of AlTi layers 13 (coating layer 11) include the part where the layers 13a5 and the layers 13a6 are located alternately one upon another in the thickness direction “a”. The layers 13a5 have a relatively small thickness and it is therefore easy to enhance adhesion. The layers 13a6 have a relatively large thickness and are therefore more likely to receive the load exerted on the coating layer 11 than the layers 13a5. Consequently, the adhesion between the adjacent layers can be enhanced in a well-balanced manner while receiving the load exerted on the coating layer 11 in a well-balanced manner.

In the first region 13a and the second region 13b adjacent to each other in the thickness direction “a” of the coating layer 11, the AlTi layer 13 located most away from the base member 9 in the first region 13a, and the AlTi layer 13 located closest to the base member 9 in the second region 13b may be in common. In the first region 13a and the second region 13b adjacent to each other in the thickness direction “a” of the coating layer 11, the AlTi layer 13 located closest to the base member 9 in the first region 13a, and the AlTi layer 13 located most away from the base member 9 in the second region 13b may be in common. If satisfying at least one of these configurations, the configuration of the coating layer 11 becomes relatively simple, thus making it easier to manufacture the coated tool 1.

Although the coated tool 1 has the quadrangular plate shape as illustrated in FIG. 1 in the first non-limiting embodiment, the shape of the coated tool 1 is not limited thereto. There is no problem even if the first surface 3 and the third surface 8 may have, for example, a triangular shape, a hexagonal shape or a circular shape instead of the quadrangular shape.

The coated tool 1 includes a through hole 17 in the first non-limiting embodiment as illustrated in FIG. 1. The through hole 17 is extended from the first surface 3 to the third surface 8 located on opposite side of the first surface 3 in the first non-limiting embodiment, and the through hole 17 opens into these surfaces. The through hole 17 is usable for attaching a screw or clamping member when holding the coated tool 1 onto a holder. There is no problem even if the through hole 17 opens into regions located on opposite sides in the second surface 5.

Examples of material of the base member 9 include inorganic materials, such as cemented carbide, cermet and ceramics. Examples of composition of cemented carbide include WC(tungsten carbide)-Co, WC—TiC(titanium carbide)-Co and WC—TiC—TaC(tantalum carbide)-Co. Specifically, WC, TiC and TaC are hard particles, and Co is a binding phase. The cermet is a sintered composite material obtainable by compositing metal into a ceramic component. Specific examples of the cermet include compounds composed mainly of TiC or TiN (titanium nitride). The material of the base member 9 is not limited to these materials.

The coating layer 11 can be located on the base member 9 by using, for example, physical vapor deposition (PVD) method. In cases where the coating layer 11 is deposited with the base member 9 held on an inner peripheral surface of the through hole 17 by using the above vapor deposition method, the coating layer 11 can be located so as to cover the entirety of the surface of the base member 9 except for the inner peripheral surface of the through hole 17.

Examples of the physical deposition method include ion plating method and sputtering method. As a non-limiting embodiment of the deposition with the ion plating method, the coating layer 11 can be deposited using the following method.

In a first procedure, a metal target independently including aluminum and titanium, a composite alloy target or a sintered body target is prepared. The above target serving as a metal source is vaporized and ionized by an arc discharge and a glow discharge. The ionized target is reacted with nitrogen (N₂) gas as a nitrogen source, and methane (CH₄) gas or acetylene (C₂H₂) gas as a carbon source, and is deposited on the surface of the base member 9. The AlTi layer 13 is formable through the above procedure.

In a second procedure, a metal target independently including aluminum and chromium, a composite alloy target or a sintered body target is prepared. The above target serving as a metal source is vaporized and ionized by an arc discharge and a glow discharge. The ionized target is reacted with nitrogen (N₂) gas as a nitrogen source, and methane (CH₄) gas or acetylene (C₂H₂) gas as a carbon source, and is deposited on the surface of the base member 9. The AlCr layer 15 is formable through the above procedure.

The coating layer configured so that a plurality of AlTi layers 13 and a plurality of AlCr layers 15 are alternately laminated one upon another is formable by alternately repeating the first procedure and the second procedure. There is no problem even if the first procedure is carried out after the second procedure.

By changing the thickness of the AlTi layers 13 so that the first regions 13a and the second regions 13b are located alternately one upon another in the thickness direction “a” when repeating the first procedure, it is possible to manufacture the coating layer 11 including the plurality of first regions 13a and the plurality of second regions 13b.

### Second Non-Limiting Embodiment

A coated tool in a second non-limiting embodiment of the present disclosure is described below in detail with reference to the drawings. The following description is mainly focused on differences from the first non-limiting embodiment. Therefore, the descriptions in the first non-limiting embodiment are applicable to descriptions of configurations similar to those in the first non-limiting embodiment, and the corresponding descriptions are omitted here.

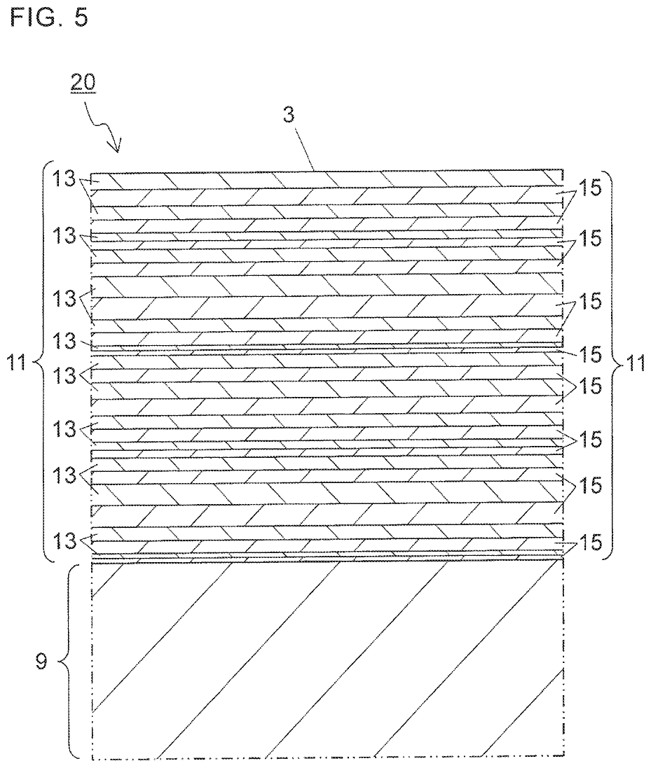

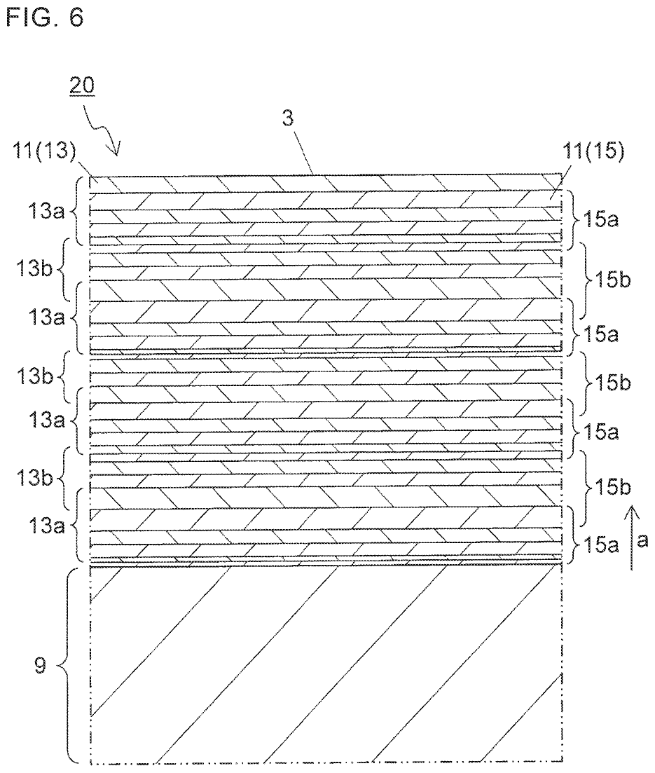

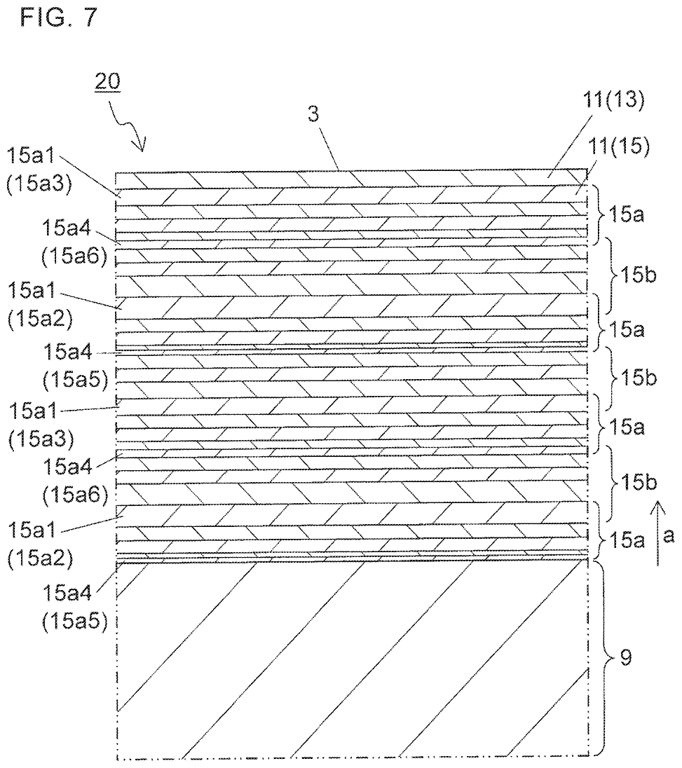

A plurality of AlCr layers 15 in the coated tool 20 in the second non-limiting embodiment may include the same configuration as the plurality of AlTi layers 13 in the first non-limiting embodiment. Specifically, the coating layer 11 may include a plurality of third regions 15a where the thickness of each of the AlCr layers 15 becomes larger as going away from the base member 9, and a plurality of fourth regions 15b where the thickness of each of the AlCr layers 15 becomes smaller as going away from the base member 9 as illustrated in FIGS. 5 and 6. The third regions 15a and the fourth regions 15b may be located alternately one upon another in a thickness direction “a” of the coating layer 11. If satisfying these configurations, the coated tool 20 has excellent durability as described later.

Because the coating layer 11 includes the third regions 15a and the fourth regions 15b in the second non-limiting embodiment as described above, the individual AlCr layers 15 do not have a constant thickness. Some of the AlCr layers 15 have a relatively large thickness, and some of them have a relatively small thickness.

Thus, the coating layer 11 includes the plurality of AlCr layers 15 having the relatively large thickness. Even when the coating layer 11 is subjected to a load, such as internal stress due to deformation with a load in use or due to differential shrinkage during manufacturing, the load tends to be absorbed in the layers having the relatively large thickness. The coating layer 11 is therefore less susceptible to cracking. The coating layer 11 also includes the plurality of AlCr layers 15 having the relatively small thickness, and these contribute to enhancing strength of the coating layer 11. The durability of the coating layer 11 can be enhanced because the coating layer 11 is less susceptible to cracking and has the enhanced strength as described above.

Similarly to the first region 13a, the thickness of each of the AlCr layers 15 becomes larger as going away from the base member 9 in the third regions 15a, and the thickness of each of the AlCr layers 15 becomes smaller as going away from the base member 9 in the fourth regions 15b. Hence, a region where the thickness of the AlCr layers 15 changes extremely is less likely to occur inside the coating layer 11. The coating layer 11 is therefore less susceptible to cracking, thereby further enhancing durability.

Additionally, the third regions 15a and the fourth regions 15b are located alternately one upon another in the thickness direction “a” of the coating layer 11 in the second non-limiting embodiment. This ensures that the AlCr layers 15 having the relatively large thickness and the AlCr layers 15 having the relatively small thickness are located in a wide range in the thickness direction “a” in the coating layer 11. Hence, the above load can be absorbed in the wide range in the thickness direction “a” in the coating layer 11, and the strength can also be enhanced, thereby enhancing the durability of the coating layer 11 as a whole.

The number of the AlCr layers 15 in each of the third regions 15a and the fourth regions 15b may be three or more, and is settable to, for example, 3 to 20. The number of the AlCr layers 15 in the individual third regions 15a may be identical or different. Similarly, the number of the AlCr layers 15 in each of the fourth regions 15b may be identical or different. The number of the third regions 15a and the number of the fourth regions 15b may be two or more, and are settable to, for example, 2 to 100.

By changing the thickness of the AlCr layers 15 so that the third regions 15a and the fourth regions 15b are located alternately one upon another in the thickness direction “a” during repetition of the second procedure with the ion plating method, it is possible to manufacture the coating layer 11 including the plurality of third regions 15a and the plurality of fourth regions 15b.

The AlCr layers 15 located most away from the base member 9 in each of the plurality of third regions 15a is a first AlCr layer 15a1. The number of the AlCr layers 15 located each between the plurality of first AlCr layers 15a1 may be approximately the same. In other words, a plurality of first AlCr layers 15a1 may be periodically located in the thickness direction “a” of the coating layer 11. If satisfying this configuration, the plurality of first AlCr layers 15a1 are regularly located inside the coating layer 11. Therefore, a load exerted on the coating layer 11 can be received in a well-balanced manner, leading to enhanced durability.

The number of the AlCr layers 15 located each between the plurality of first AlCr layers 15a1 is not limited to a specific value, but it is settable to, for example, 2 to 40. The phrase that “the number of the AlCr layers 15 located each between the plurality of first AlCr layers 15a1 is approximately the same” can be defined similarly to the phrase that “the number of the AlTi layers 13 located each between the plurality of first AlTi layers 13a1 is approximately the same”.

The plurality of first AlCr layers 15a1 may have the same thickness. Alternatively, in the first AlCr layers 15a1 in the third regions 15a adjacent to each other, a magnitude relation in terms of thickness value may be repeated in the thickness direction “a” of the coating layer 11. In other words, the plurality of first AlCr layers 15a1 (coating layer 11) may further include a part where layers 15a2 having a relatively large thickness and layers 15a3 having a relatively small thickness are located alternately one upon another, in the thickness direction “a” of the coating layer 11.

If the plurality of first AlCr layers 15a1 include the part where the layers 15a2 and the layers 15a3 are located alternately one upon another, the plurality of AlCr layers 15 (coating layer 11) include the part where the layers 15a2 and the layers 15a3 are located alternately one upon another in the thickness direction “a”. The layers 15a2 have the relatively large thickness and therefore tend to receive the load exerted on the coating layer 11. The layers 15a3 have the relatively small thickness, and therefore adhesion is less likely to deteriorate. Consequently, the adhesion between the adjacent layers can be enhanced in a well-balanced manner while receiving the load exerted on the coating layer 11 in a well-balanced manner.

The AlCr layers 15 located closest to the base member 9 in each of the plurality of third regions 15a is a second AlCr layer 15a4. The number of the AlCr layers 15 located each between the second AlCr layers 15a4 may be approximately the same. In other words, the plurality of second AlCr layers 15a4 may be periodically located in the thickness direction “a” of the coating layer 11. If satisfying this configuration, the plurality of second AlCr layers 15a4 are located regularly inside the coating layer 11. Therefore, adhesion between the adjacent layers can be enhanced in a well-balanced manner.

The number of the AlCr layers 15 located each between the plurality of second AlCr layers 15a4 is not limited to a specific value, but it is settable to, for example, 2 to 40. The phrase that “the number of the AlCr layers 15 located each between the plurality of second AlCr layers 15a4 is approximately the same” can be defined similarly to the phrase that “the number of the AlTi layers 13 located each between the plurality of first AlTi layers 13a1 is approximately the same.”

The plurality of second AlCr layers 15a4 may have the same thickness. Alternatively, a magnitude relation in terms of thickness value may be repeated in the thickness direction “a” of the coating layer 11 in the second AlCr layers 15a4 in the adjacent third regions 15a. In other words, the plurality of second AlCr layers 15a4 (coating layer 11) may further include a part where layers 15a5 having a relatively small thickness and layers 15a6 having a relatively large thickness are located alternately one upon another in the thickness direction “a” of the coating layer 11.

If the plurality of second AlCr layers 15a4 include the part where the layer 15a5 and the layer 15a6 are located alternately one upon another, the plurality of AlCr layers 15 (coating layer 11) include the part where the layers 15a5 and the layers 15a6 are located alternately one upon another in the thickness direction “a”. The layers 15a5 have the relatively small thickness and it is therefore easy to enhance adhesion. The layers 15a6 have the relatively large thickness and are therefore more likely to receive the load exerted on the coating layer 11 than the layers 15a5. Consequently, the adhesion between the adjacent layers can be enhanced in a well-balanced manner while receiving the load exerted on the coating layer 11 in a well-balanced manner.

In the third region 15a and the fourth region 15b adjacent to each other in the thickness direction “a” of the coating layer 11, the AlCr layer 15 located most away from the base member 9 in the third region 15a, and the AlCr layer 15 located closest to the base member 9 in the fourth region 15b may be in common. In the third region 15a and the fourth region 15b adjacent to each other in the thickness direction “a” of the coating layer 11, the AlCr layer 15 located closest to the base member 9 in the third region 15a, and the AlCr layer 15 located most away from the base member 9 in the fourth region 15b may be in common. If satisfying at least one of these configurations, the configuration of the coating layer 11 becomes relatively simple, thus making it easier to manufacture the coated tool 20.

<Cutting Tools>

Cutting tools in various non-limiting embodiments of the present disclosure are described below with reference to the drawings.

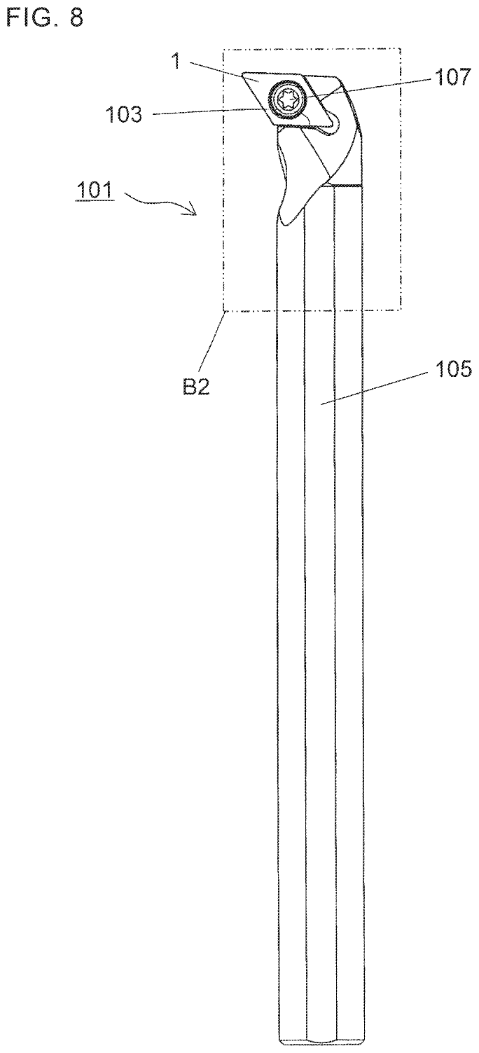

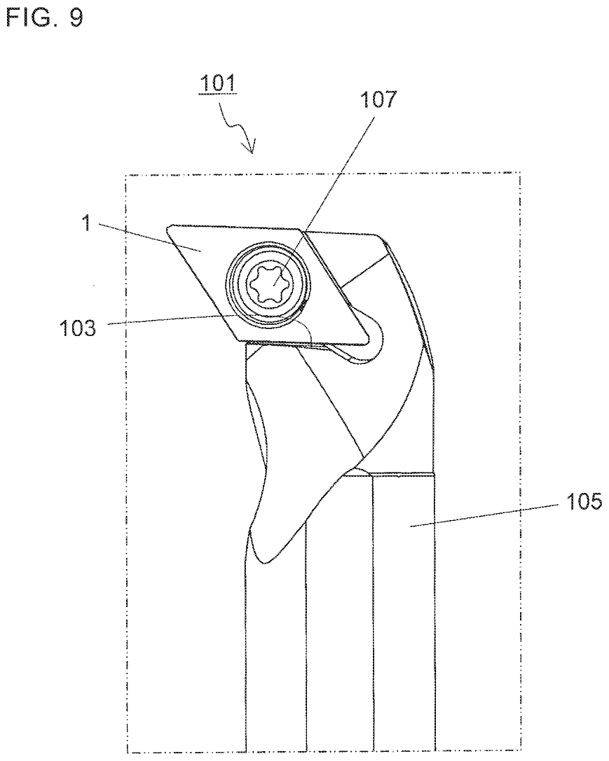

As illustrated in FIG. 8, the cutting tool 101 in a non-limiting embodiment is a bar-shaped body extended from a first end (an upper end in FIG. 8) to a second end (a lower end in FIG. 8). As illustrated in FIG. 9, the cutting tool 101 includes a holder 105 with a pocket 103 located at a side of the first end (front end), and the coated tool 1 located in the pocket 103, which is described in the first non-limiting embodiment. The cutting tool 101 including the coated tool 1 is capable of carrying out a cutting process that is stable over a long term.

The pocket 103 is a part that permits attachment of the coated tool 1. The pocket 103 includes a seating surface parallel to a lower surface of the holder 105, and a constraining side surface inclined relative to the seating surface. The pocket 103 opens into a side of the first end of the holder 105.

The coated tool 1 is located in the pocket 103. A lower surface of the coated tool 1 may be in a direct contact with the pocket 103. Alternatively, a sheet (not illustrated) may be held between the coated tool 1 and the pocket 103.

The coated tool 1 is attached so that at least a part of a ridge line where the first surface 3 intersects with the second surface 5, which is usable as the cutting edge 7, is protruded outward from the holder 105. The coated tool 1 is attached to the holder 105 by a fixing screw 107 in a non-limiting embodiment. Specifically, the coated tool 1 is attachable to the holder 105 in such a manner that screw parts are engaged with each other by inserting the fixing screw 107 into the through hole 17 of the coated tool 1, and by inserting a front end of the fixing screw 107 into a screw hole (not illustrated) formed in the pocket 103.

For example, steel and cast iron are usable as a material of the holder 105. Of these materials, high toughness steel may be used.

The non-limiting embodiments have illustrated and described the cutting tools for use in the so-called turning process. Examples of the turning process include inner diameter processing, outer diameter processing and grooving process. The cutting tools are not limited to ones which are used for the turning process. For example, the coated tools 1 of the above non-limiting embodiments are applicable to the cutting tools for use in a milling process.

The cutting tool 101 in the above non-limiting embodiment has been described by taking the case of using the coated tool 1 as a non-limiting embodiment. The coated tool 20 in the second non-limiting embodiment may be used instead of the coated tool 1.

Singular forms “a”, “an” and “the” in the entirety of the present disclosure include plural forms thereof unless clearly indicated not being so from the context.

### DESCRIPTION OF THE REFERENCE NUMERALS

1 coated tool
3 first surface
3a rake surface region
5 second surface
5a flank surface region
7 cutting edge
8 third surface
9 base member
11 coating layer
13 AlTi layer
13a first region
13a1 first AlTi layer
13a4 second AlTi layer
13b second region
15 AlCr layer
15a third region
15a1 first AlCr layer
15a4 second AlCr layer
15b fourth region
17 through hole
20 coated tool
101 cutting tool
103 pocket
105 holder
107 fixing screw

1. A coated tool, comprising:
a base member; and
a coating layer located on the base member, wherein
the coating layer comprises:
a plurality of AlTi layers comprising aluminum and titanium and a plurality of AlCr layers comprising aluminum and chromium, respective AlTi layers of the plurality of AlTi layers and respective AlCr layers of the plurality of AlCr layers being located alternately one upon another,
a plurality of first regions where a thickness of each AlTi layer in the plurality of first regions increases going away from the base member,
a plurality of second regions where a thickness of each AlTi layer decreases going away from the base member,
and
respective first regions of the plurality of first regions and respective second regions of the plurality of second regions are located alternately one upon another in a thickness direction of the coating layer.

2. The coated tool according to claim 1, wherein
an AlTi layer of the plurality of AlTi layers located farthest away from the base member in each of the plurality of first regions is identified as a first AlTi layer, and
a substantially regular number of AlTi layers are located between adjacent first AlTi layers.

3. The coated tool according to claim 1, wherein
an AlTi layer of the plurality of AlTi layers located farthest away from the base member in each of the plurality of first regions is identified as a first AlTi layer, and
a magnitude relation in terms of thickness value is repeated in the thickness direction of the coating layer in respective first AlTi layers in adjacent first regions.

4. The coated tool according to claim 1, wherein
an AlTi layer of the plurality of AlTi layers located closest to the base member in each of the plurality of first regions is identified as a second AlTi layer, and
a substantially regular number of AlTi layers are located between adjacent second AlTi layers.

5. The coated tool according to claim 1, wherein
an AlTi layer of the plurality of AlTi layers located closest to the base member in each of the plurality of first regions is identified as a second AlTi layer, and
a magnitude relation in terms of thickness value is repeated in the thickness direction of the coating layer in respective second AlTi layers in adjacent first regions.

6. The coated tool according to claim 1, wherein
the coating layer further comprises:
a plurality of third regions where a thickness of each AlCr layer in the plurality of third regions increases going away from the base member,
a plurality of fourth regions where a thickness of each AlCr layer in the plurality of fourth regions decreases going away from the base member, and
respective third regions of the plurality of third regions and respective fourth regions of the plurality of fourth regions are located alternately one upon another in the thickness direction of the coating layer.

7. A cutting tool, comprising:
a holder comprising a pocket located at a side of a front end of the holder; and
the coated tool according to claim 1, the coated tool being located in the pocket.
